(19) United States
(12) Patent Application Publication
(10) Pub. No.: US 2005/0288457 A1
(43) Pub. Date: Dec. 29, 2005

(54) Co-curable compositions

(76) Inventors: Puwei Liu, San Diego, CA (US); Benjamin Neff, San Diego, CA (US); Zhengjue Zhang, San Diego, CA (US); Kang Yang, San Diego, CA (US)

Correspondence Address: Steven C Bauman;Henkel Corporation, Legal Department, 1001 Trout Brook Crossing, Rocky Hill, CT, 06067, US

(21) Appl. No.: 10/531,723

(22) PCT Filed: Oct. 20, 2003
(86) PCT No.: PCT/US03/33243

§ 371 Date: Apr. 18, 2005

Related U.S. Application Data
(60) Provisional application No. 60/419,957, filed on Oct. 22, 2002.

(51) Int. Cl. C08L 63/00; H01L 21/50; B32B 27/38

(52) U.S. Cl. 525/529; 525/535; 438/118; 428/413; 428/414

(57) ABSTRACT

The present invention provides co-curable compositions in which an anionically or cationically reactive component, such as an epoxy or episulfide resin component; a free-radical polymerizable component; and a cross linking component, where the cross linking component is reactive with each of the anionically or cationically reactive component and the free radical polymerizable component through functionalization with at least one group reactive through an anionic or cationic mechanism and at least one group reactive through a free radical mechanism. The invention further provides methods of preparing such compositions, methods of applying such compositions to substrate surfaces, and assemblies prepared therewith for connecting microelectronic circuitry.

### BACKGROUND OF THE INVENTION

1. Field of the Invention

The present invention provides co-curable compositions in which an anionically or cationically reactive component, such as an epoxy or episulfide resin component; a free radical polymerizable component; and a cross linking component, where the cross linking component is reactive with each of the anionically or cationically reactive component and the free radical polymerizable component through functionalization with at least one group reactive through an anionic or cationic mechanism and at least one group reactive through a free radical mechanism. The invention further provides methods of preparing such compositions, methods of applying such compositions to substrate surfaces, and packages and assemblies prepared therewith for connecting microelectronic circuitry.

2. Brief Description of Related Technology

Bismaleimides occupy a prominent position in the spectrum of thermosetting resins, and a number of bismaleimides are commercially available. Bismaleimides have been used for the production of moldings and adhesive joints, heat-resistant composite materials, and high temperature coatings. More recently, Henkel Loctite Corporation has commercialized a number of products based in part on certain bismaleimides for the attachment of semiconductor chips to circuit boards, which have received favorable responses from within the microelectronic industry. These products are covered in one or more of U.S. Pat. No. 5,789,757 (Husson), U.S. Pat. No. 6,034,194 (Dershem), U.S. Pat. No. 6,034,195 (Dershem) and U.S. Pat. No. 6,187,886 (Husson).

Even more widely used are epoxy resins, particularly in microelectronic packaging and assembly applications.

Bismaleimides and epoxy resins have been used in tandem in curable compositions in the past; however, such compositions would form an interpenetrating network, as epoxies and maleimides react through different mechanisms and thus not with themselves. Alternatively, in the precense of an amine curative, the amine would cure the epoxy and can react with the maleimide through a Michael addition reaction.

U.S. Pat. No. 6,300,456 (Musa) refers to compounds containing both electron donor—olefinic—and electron acceptor—maleimide, acrylate, fumarate, and maleate—functionality for use in adhesives. In these compounds both the electron donor and the electron acceptor are curable by free radical mechanisms.

It would desirable however to provide a curable composition that enjoys the benefits of both epoxies (anionically or cationically curable) and maleimides (free radically cuarble), and which demonstrates improvements in certain physical properties. However, in order to provide commercially attractive curable compositions particularly well suited for microelectronic packaging and assembly applications, the reaction of maleimides with epoxies should desirably occur through the introduction of another material, other than a simple amine, that reacts with both types of compounds—one in a free radical mechanism and the other in an anionic or cationic mechanism. By so doing, one would form a co-curable composition, rather than an interpenetrating network of two discrete polymerized phases. Until now, this is not believed to have been reported or observed.

### SUMMARY OF THE INVENTION

The present invention is directed to co-curable compositions, which includes an anionically or cationically reactive component, such as an epoxy or episulfide resin component; a free radical polymerizable component; and a cross linking component. The cross linking component includes a compound reactive with each of the epoxy resin component and the free radical polymerizable component.

The inventive compositions may also include a radical cure inducing component for the free radical polymerizable component and/or a curative for the anionically or cationically reactive component, such as the epoxy or episulfide resin component. The radical cure inducing component may be a radical heat cure catalyst or a radical photocure catalyst (also called, a photoinitiator).

The present invention also provides inventive cross-linking compounds, a method of making the inventive compositions, a method of co-curing the inventive compositions, a method of adhesively attaching a semiconductor chip to a substrate, and an article of manufacture, and in particular, a semiconductor chip which is attached to and in electrical interconnection with a carrier substrate. That is, the invention provides an article of manufacture comprising a semiconductor chip attached to and in electrical interconnection with either another semiconductor chip or a carrier substrate, the semiconductor chip having a first surface and a second surface, with the first surface having electrical contacts arranged in a predetermined pattern thereon for providing electrical engagement with the another semiconductor chip or the carrier substrate, respectively, and with the second surface having a cured inventive composition disposed on a layer or a portion thereof, so as to provide attachment between the semiconductor chip and the another semiconductor chip or the carrier substrate, respectively.

### DETAILED DESCRIPTION OF THE INVENTION

As noted above, the present invention is directed to co-curable compositions, which includes an anionically or cationically reactive component, such as an epoxy or episulfide resin component; a free radical polymerizable component; and a cross linking component. The cross linking component includes a compound reactive with each of the epoxy resin component and the free radical polymerizable component.

The anionically or cationically reactive component should be present in an amount of about 2 weight percent to about 98 weight percent, such as about 4 weight percent to about 20 weight percent, desirable about 5 weight percent to about 10 weight percent.

The free radical polymerizable component should be present in an amount of about 2 weight percent to about 98 weight percent, such as about 4 weight percent to about 20 weight percent, desirable about 5 weight percent to about 10 weight percent.

The cross linking component should be present in an amount of about 0.01 to about 30 weight percent, about 0.05 weight percent to about 15 weight percent, desirably about 0.1 weight percent to about 5 weight percent.

The anionically or cationically reactive component, as noted above, may be an epoxy or episulfide resin. Speaking in terms of epoxy resin (though applicable to episulfide resins, as well), the epoxy resin may be comprised of at least one multifunctional epoxy resin, optionally, together with at least one monofunctional epoxy resin.

A monofunctional epoxy resin, if present, should ordinarily be used as a reactive diluent, or crosslink density modifier. The monofunctional epoxy resin should have an epoxy group with an alkyl group of about 4 to about 28 carbon atoms, examples of which include C₄-C₂₈ alkyl glycidyl ethers, C₄-C₂₈ alkenyl glycidyl esters and C₂-C₂₈ alkylphenol glycidyl ethers.

Multifunctional epoxy resins include generally, but are not limited to, polyglycidyl ethers of polyvalent phenols, for example pyrocatechol; resorcinol; hydroquinone; 4,4′-dihydroxydiphenyl methane; 4,4′-dihydroxy-3,3′-dimethyldiphenyl methane; 4,4′-dihydroxydiphenyl dimethyl methane; 4,4′-dihydroxydiphenyl methyl methane; 4,4′-dihydroxydiphenyl cyclohexane; 4,4′-dihydroxy-3,3′-dimethyldiphenyl propane; 4,4′-dihydroxydiphenyl sulfone; tris(4-hydroxyphyenyl)methane; polyglycidyl ethers of the chlorination and bromination products of the above-mentioned diphenols; polyglycidyl ethers of novolacs (i.e., reaction products of monohydric or polyhydric phenols with aldehydes, formaldehyde in particular, in the presence of acid catalyst; polyglycidyl ethers of diphenols obtained by esterifying 2 moles of the ethers of diphenols obtained by esterifying 2 moles of the sodium slat of an aromatic hydrocarboxylic acid with 1 mole of a dihaloalkane or dihalogen dialkyl ether (see U.K. Pat. No. 1,017,612, the disclosure of which is hereby expressly incorporated herein by reference); and polyglycidyl ethers of polyphenols obtained by condensing phenols and long-chain halogen paraffins containing at least two halogen atoms (see U.K. Pat. No. 1,024,288, the disclosure of which is hereby expressly incorporated herein by reference).

Other suitable epoxy resins include polyepoxy compounds based on aromatic amines and epichlorohydrin, such as N,N′-diglycidyl-aniline; N,N′-dimethyl-N,N′-diglycidyl-4,4′diaminodiphenyl methane; N,N,N′,N′-tetraglycidyl-4,4′diaminodiphenyl methane; N-diglycidyl-4-aminophenyl glycidyl ether; and N,N,N′,N′-tetraglycidyl-1,3-propylene bis-4-aminobenzoate.

Among the epoxy resins suitable for use herein are polyglycidyl derivatives of phenolic compounds, such as those available commercially under the tradenames EPON 828, EPON 1001, EPON 1009, EPON 1031, EPON 8132 and EPON 815C from Resolution Performance; DER 331, DER 332, DER 334, and DER 542 from Dow Chemical Co.; and BREN-S from Nippon Kayaku, Japan. Other suitable epoxy resins include polyepoxides prepared from polyols and the like and polyglycidyl derivatives of phenol-formaldehyde novolacs, the latter of which are available commercially under the tradenames DEN 431, DEN 438, and DEN 439 from Dow Chemical Company. Cresol analogs are also available commercially under the ARALDITE tradename as ECN 1235, ECN 1273, and ECN 1299 from Vantico Inc. SU-8 is a bisphenol A-type epoxy novolac available from Resolution Performance. Polyglycidyl adducts of amines, aminoalcohols and polycarboxylic acids are also useful in this invention, commercially available resins of which include GLYAMINE 135, GLYAMINE 125, and GLYAMINE 115 from F.I.C. Corporation; ARALDITE MY-720, ARALDITE 0500, and ARALDITE 0510 from Vantico, Inc. and PGA-X and PGA-C from the Sherwin-Williams Co.

And of course combinations of the different epoxy resins are also desirable for use herein.

In choosing epoxy resins for the epoxy resin component of the compositions of the present invention, consideration should also be given to viscosity and other properties thereof.

Of course, full or mixed sulfur versions of these epoxies may be used as well, whether alone, in combination, or in combination with the epoxy resin.

Another anionically or cationically curable component includes benzoxazines, which are typically prepared by reacting a phenolic compound, such as a bisphenol A or bisphenol F, with an aldehyde and an amine, desirably an aromatic amine. U.S. Pat. No. 5,543,516, hereby expressly incorporated herein by reference, describes a method of forming benzoxazines, where the reaction time can vary from a few minutes to a few hours, depending on reactant concentration, reactivity and temperature. See also U.S. Pat. No. 4,607,091 (Schreiber), U.S. Pat. No. 5,021,484 (Schreiber), U.S. Pat. No. 5,200,452 (Schreiber) and U.S. Pat. No. 5,443,911 (Schreiber).

The benzoxazines have high glass transition temperature, good electrical properties (e.g., dielectric constant), low flammability, and a near-zero percent shrinkage and expansion upon demolding, postcuring, and cooling.

Benzoxazines useful in the present invention may have the following structure:
Rₓ—Ar(Q)ₙ
where

L is an optional alkylene or siloxane linking moiety,

Ar is optionally substituted arylene,

Q is an oxazine ring or amine salt thereof having the structure: 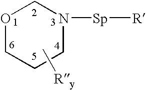
and is bonded to Ar in a fused manner at positions 5 and 6 of the oxazine ring,
where

Sp is optional, and if present, is a C₁₋₆ alkylene, oxy alkylene, thio alkylene, carboxy alkylene, amido alkylene or sulfonato alkylene spacer,

n is 1 or 2,

x and y are each independently 0 to 4, and where at least one of R′ and R″ may be a polymerizable moiety, which participates in a polymerization reaction, such as, for example, an addition polymerization or a condensation polymerization. Polymerizable moieties include, for example, optionally substituted alkenyl, oxyalkenyl, alkynyl, cycloalkenyl, bicycloalkenyl, styryl, (meth)acrylate, maleimide, itaconimide, nadimide, vinyl ester, epoxy, cyanate ester, nitrile, diallyl amide, benzocyclobutene, aromatic propargyl ether, aromatic acetylene, oxazoline, and the like, with alkenyl, oxyalkenyl, (meth)acrylate, maleimide, or cycloalkenyl being particularly desirable.

The benzoxazine may be in the liquid state at room temperature and may optionally be functionalized depending on the specific application, such as, for example, with alcohols, amines, silane esters, thiols, isocyanates, anhydrides, and the like.

The benzoxaziness may contain one or two oxazine rings per aryl ring, represented by the following exemplary structures A and B, respectively: 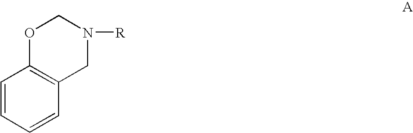
such as

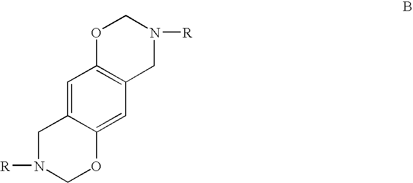

An optionally substituted arylene is naphthylene, represented by the following exemplary structure C:

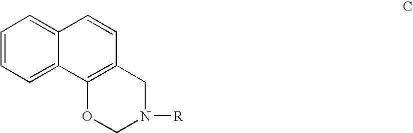

Certain benzoxazines are available from Vantico, Inc. and Georgia-Pacific Resins, Inc. Certain of these benzoxazine resins available from Georgia-Pacific, such as GP834D54, are described as having been developed for use in electronic molding compound applications and electrical laminates. These benzoxazine resins are reported to offer high Tg, minimal shrinkage, low moisture absorption, low ionics and low viscosity at mold temperatures. These benzoxazines cure by a non-volatile ring opening polymerization at elevated temperatures. However, use of a strong acid or base catalyst can significantly accelerate low-temperature curing. It is known that the addition of certain cycloaliphatic epoxies to the benzoxazine decreases the cure speed and improves end use properties thereof. And certain benzoxazines from Vantico, such as RD 99-009, are available as blends with such epoxies. RD 99-009 is described as a mixture of 7-oxabicyclo[4.1.0]heptane-3-carboxylic acid, 7-oxabicyclo[4.1.0]hept-3-ylmethyl ester (CAS No. 2386-87-0) and 3,4-epoxycyclohexylmethyl 3,4-epoxycyclohexane carboxylate.

Other commercial sources of benzoxozines include Shikoku Chemicals Corporation, Chiba, Japan, which offers B-a and B-m, F-a, C-a and F-a benzoxazine resins, and P-a benzoxazine reactive diluents and Hycomp, Inc., which offers a benzoxazine known as HyComp 500 resin.

Suitable benzoxazine resins can be prepared by condensing two equivalents of formaldehyde with one equivalent of a primary amine (e.g., methylamine and aniline) and reacting with one equivalent of phenol (e.g., bisphenol-A). See e.g. Burke et al., J. Org. Chem., 30(10), 3423 (1965).

Other suitable anionically or cationically curable components include oxazolines and cyanate esters.

The oxazoline resins particularly useful in the inventive composition include those having at least two oxazoline, two oxazine, or two tetrahydrooxazepine groups per molecule and/or molecules with both an oxazoline and an oxazine, an oxazoline and tetrahydrooxazepine or an oxazine and tetrahydrooxazepine residue on the same molecule.

Bisoxazolines, bisoxazines, and bis-tetrahydrooxazepines compounds or compounds with mixed oxazoline, oxazine, and tetrahydrooxazepine moieties in the same molecules include mixtures of two or more compounds within the following formula: 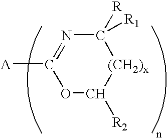
where A represents a cyclic or acyclic aliphatic moiety, with or without substituted having from 1 to 20 carbon atoms, or an aromatic mono- or multinuclear, with or without aliphatic substituted, having from 6 to 20 carbon atoms;

R independently represents H, alkyl, such as CH₃ or CH₂CH₃, or phenyl, such as C₆H₅;

R¹ and R² independently represents H or alkyl, such as CH₃;

n represents the integer 1 or 2; and

x represents an integer from 0 to 2.

Examples of oxazolines which may be used in the inventive compositions include those described in U.S. Pat. No. 4,806,267 (Culbertson), the disclosure of which is hereby incorporated herein by reference.

Cyanate esters may also be used in the inventive compositions. The cyanate esters useful as a component in the inventive compositions may be chosen from dicyanatobenzenes, tricyanatobenzenes, dicyanatonaphthalenes, tricyanatonaphthalenes, dicyanato-biphenyl, bis(cyanatophenyl)methanes and alkyl derivatives thereof, bis(dihalocyanatophenyl)propanes, bis(cyanatophenyl)ethers, bis(cyanatophenyl)sulfides, bis(cyanatophenyl)propanes, tris(cyanatophenyl)phosphites, tris(cyanatophenyl)phosphates, bis(halocyanatophenyl)methanes, cyanated novolac, bis[cyanatophenyl(methylethylidene)]benzene, cyanated bisphenol-terminated thermoplastic oligomers, and combinations thereof.

More specifically, aryl compounds having at least one cyanate ester group on each molecule and may be generally represented by the formula Ar(OCN)ₘ, where Ar is an aromatic radical and m is an integer from 2 to 5. The aromatic radical Ar should contain at least 6 carbon atoms, and may be derived, for example, from aromatic hydrocarbons, such as phenyl, biphenyl, naphthalene, anthracene, or the like. The aromatic radical Ar may also be derived from a polynuclear aromatic hydrocarbon in which at least two aromatic rings are attached to each other through a bridging group. Also included are aromatic radicals derived from novolac-type phenolic resins—i.e., cyanate esters of these phenolic resins. Ar may also contain further ring-attached, non-reactive substituents.

Examples of such cyanate esters include, for instance, 1,3-dicyanatobenzene; 1,4-dicyanatobenzene; 1,3,5-tricyanatobenzene; 1,3-, 1,4-, 1,6-, 1,8-, 2,6- or 2,7-dicyanatonaphthalene; 1,3,6-tricyanatonaphthalene; 4,4′-dicyanato-biphenyl; bis(4-cyanatophenyl)methane and 3,3′,5,5′-tetramethyl bis(4-cyanatophenyl)methane; 2,2-bis(3,5-dichloro-4-cyanatophenyl)propane; 2,2-bis(3,5-dibromo-4-dicyanatophenyl)propane; bis(4-cyanatophenyl)ether; bis(4-cyanatophenyl)sulfide; 2,2-bis(4-cyanatophenyl)propane; tris(4-cyanatophenyl)-phosphite; tris(4-cyanatophenyl)phosphate; bis(3-chloro-4-cyanatophenyl)methane; cyanated novolac; 1,3-bis[4-cyanatophenyl-1-(methylethylidene)]benzene and cyanated bisphenol-terminated polycarbonate or other thermoplastic oligomer.

Other cyanate esters include cyanates disclosed in U.S. Pat. Nos. 4,477,629 and 4,528,366, the disclosure of each of which is hereby expressly incorporated herein by reference; the cyanate esters disclosed in U.K. Pat. No. 1,305,702, and the cyanate esters disclosed in International Patent Publication WO 85/02184, the disclosure of each of which is hereby expressly incorporated herein by reference. Of course, combinations of these cyanate esters within the imidazole component of the compositions of the present invention are also desirably employed herein.

Particularly desirable cyanate esters for use herein are available commercially from Ciba Specialty Chemicals, Tarrytown, New York under the tradename “AROCY” [1,1-di(4-cyanatophenylethane)]. The structures of three “AROCY” cyanate esters are shown below:

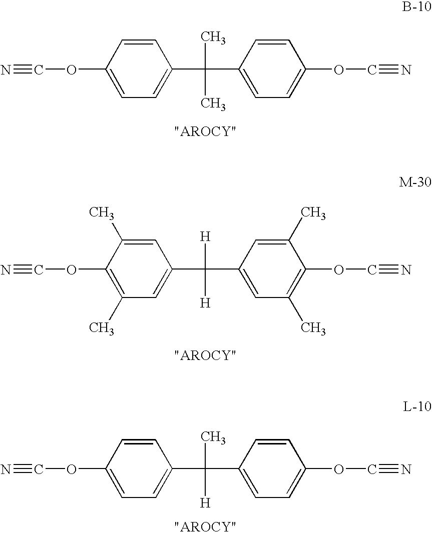

When used, the cyanate esters may be used in an amount of about 1 to about 20 weight percent, based on the total amount of the curable aromatic resin component.

Curatives for the anionically or cationically reactive component include nitrogen containing compounds, anhydrides, organic acids and Lewis acids.

For instance, as nitrogen containing compounds are amines, imidazoles, aza compounds, amides, and combinations thereof.

Examples of the amine compounds polyamines and di- and tri-aza compounds, such as

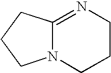

1,5-diazabicyclo[3.4.0]non-5-ene;

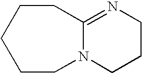

1,8-diazabicyclo[5.4.0]undec-7-ene;

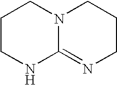

1,5,7-triazabicyclo[4.4.0]dec-5-ene; the bicyclo mono- and di-aza compounds:

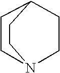

quinuclidine;

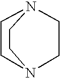

1,4-diazabicyclo[2.2.2]octane; the aliphatic polyamines:
diethylenetriamine, triethylenetetraamine, and diethylaminopropylamine;
   the aromatic polyamines:
benzyl dimethylamine, m-xylenediamine, diaminodiphenylamine and quinoxaline; and
   the alicyclic polyamines:
isophoronediamine and menthenediamine.

of course, combinations of these amine compounds are also desirable for use in the compositions of the present invention.

Examples of imidazoles include imidazole and derivatives thereof, such as isoimidazole, imidazole, alkyl substituted imidazoles, such as 2-ethyl-4-methylimidazole, 2,4-dimethylimidazole, butylimidazole, 2-heptadecenyl-4-methylimidazole, 2-methylimidazole, 2-undecenylimidazole, 1-vinyl-2-methylimidazole, 2-undecylimidazole, 2-heptadecylimidazole, 2-phenylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition products of an imidazole methylimidazole and addition products of an imidazole and trimellitic acid, 2-n-heptadecyl-4-methylimidazole and the like, generally where each alkyl substituent contains up to about 17 carbon atoms and desirably up to about 6 carbon atoms, aryl substituted imidazoles, such as phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxyl-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethylaminophenyl)-4,5-diphenylimidazole, 2-(2-hydroxyphenyl)-4,5-diphenylimidazole, di(4,5-diphenyl-2-imidazole)-benzene-1,4,2-naphthyl-4,5-diphenylimidazole, 1-benzyl-2-methylimidazole, 2-p-methoxystyrylimidazole, 2-phenyl-4,5-dihydroxymethylimidazole and the like generally where each aryl substituent contains up to about 10 carbon atoms and desirably up to about 8 carbon atoms.

A particularly desirable imidazole for use herein is 1-(2-cyanoethyl)-2-ethyl-4-methylimidazole, available commercially from Borregaard Synthesis Inc., Newburyport, Mass. under the tradename CURIMID CN.

Of course, combinations of these imidazoles are also desirable as the imidazole component of the latent hardener component of the compositions of the present invention.

Examples of amide compounds include cyano-functionalized amides, such as dicyandiamide or cyanoguanidine (commercially available from Air Products under the tradenames CG-1400 and CG-1600).

Of course, combinations of these various nitrogen containing compounds are also desirable for use in the compositions of the present invention.

The organic acid may be selected from phenolics, thiophenolics, thiols or carboxylic acids.

As a free radically polymerizable component a variety of different classes of compounds are available. For instance, maleimides, itaconimides, nadimides, (meth)acrylates, fumarates, maleates, vinyl ethers, vinyl esters, styrene and derivatives thereof, poly(alkenylene)s, allyl amides, norbornenyls, thiolenes, acrylonitriles and combinations thereof may be used.

The maleimides, itaconimides and nadimides include those compounds having the following structures I, II and III, respectively 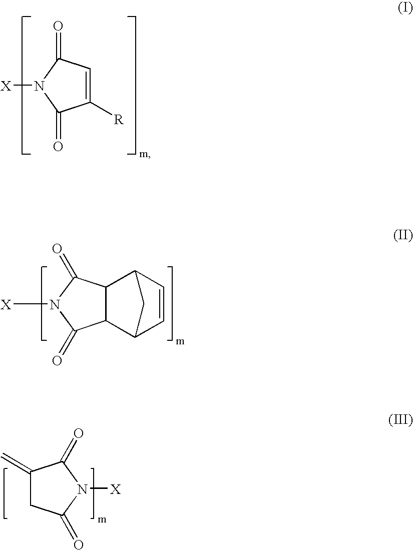
where

m=1-15,

R is independently selected from hydrogen or lower alkyl, and

X is a monovalent moiety or a multivalent linking moiety comprising organic or organosiloxane radicals, and combinations thereof, such as siloxane/urethane block co-polymers.

More specific representations of the maleimides, itaconimides and nadimides include those corresponding to structures I, II and III, where

m=1-6,

R is independently selected from hydrogen or lower alkyl, and

X comprises a monovalent moiety or a multivalent linking moiety selected from straight or branched chain alkyl, alkylene, oxyalkyl, oxyalkylene, alkenyl, alkenylene, oxyalkenyl, oxyalkenylene, ester, reverse ester, polyester, amide, reverse amide, or polyamide, optionally interrupted or substituted by one or more heteroatoms, such as oxygen, nitrogen and/or sulfur, and optionally functionalized with substituents selected from hydroxy, alkoxy, carboxy, nitrile, cycloalkyl or cycloalkenyl, where the number of carbon atoms in the linking moeity falls between about 12 to about 500;

of the siloxanes comprise:

—(CR₂)_{m′}—[Si(R′)₂—O]_{q}′—Si(R′)₂—(CR₂)_{n′}—, —(CR₂)ₘ—CR—C(O)O—(CR₂)_{m′}—[Si(R′)₂—O]_{q′}—Si(R′)₂—(CR₂)_{n′}—O(O)C—(CR₂)_{n′}— or —(CR₂)_{m′}—CR—O(O)C—(CR₂)_{m′}—[Si(R′)₂—O]_{q′}—Si(R′)₂—(CR₂)_{n′}—C(O)O—(CR₂)_{n′}—,

where each R is independently defined as above, and each R′ is independently selected from hydrogen, lower alkyl or aryl, m′ falls in the range of 1 up to 10, n′ falls in the range of 1 up to 10, and q′ falls in the range of 1 up to 50;

of the polyalkylene oxides comprise:
[(CR₂)ᵣ—O—]_{q′}—(CR₂)ₛ—
where each R is independently as defined above, r falls in the range of 1 up to 10, s falls in the range of 1 up to 10, and q′ is as defined above;

of the aromatic moieties comprise: 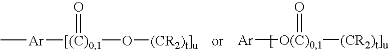
where each R is independently as defined above, t falls in the range of 2 up to 10, u is 1, 2 or 3, and Ar is as defined above, or 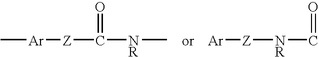
where Z is O or NR, where R is hydrogen or lower alkyl; of the urethanes comprise: 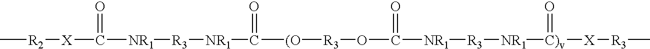
where each R₁ is independently hydrogen or lower alkyl; each R₂ independently is an alkyl, aryl, or arylalkyl group having 1 to 18 carbon atoms; R₃ is an alkyl or alkyloxy chain having up to about 100 atoms in the chain, which chain may contain aryl substituents; X is O, S, N, or P; and v is 0 to 50; and

of the aromatic moieties comprise: 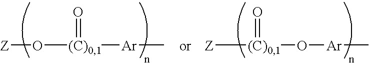
where each Ar is a monosubstituted, disubstituted or trisubstituted aromatic or heteroaromatic ring having in the range of 3 up to about 10 carbon atoms; n is 1 up to about 50, and Z is selected from straight or branched chain alkyl, alkylene, oxyalkylene, alkenyl, alkenylene, oxyalkenylene, ester, or polyester, optionally containing substituents selected from hydroxy, alkoxy, carboxy, nitrile, cycloalkyl or cycloalkenyl; siloxanes comprising:
—(CR₂)_{m′}—[Si(R′)₂—O]_{q′}—Si(R′)₂—(CR₂)_{n′}—, —(CR₂)_{m′}—CR—C(O)O—(CR₂)_{m′}—[Si(R′)₂—O]_{q′}—Si(R′)₂—(CR₂)_{n′}—O(O)C—(CR₂)_{n′}—, or —(CR₂)_{m′}—CR—O(O)C—(CR₂)_{m′}—[Si(R′)₂—O]_{q′}—Si (R′)₂—(CR₂)_{n′}—C(O)O—(CR₂)_{n′}—,
where each R is independently defined as above, and each R′ is independently selected from hydrogen, lower alkyl or aryl, m′ falls in the range of 1 up to 10, n′ falls in the range of 1 up to 10, and q′ falls in the range of 1 up to 50; and

of the polyalkylene oxides comprise:
—[(CR₂)ᵣ—O—]_{q′}—(CR₂)ₛ—
where each R is independently as defined above, r falls in the range of 1 up to 10, s falls in the range of 1 up to 10, and q′ is as defined above; as well as combinations thereof.

In a particularly desirable aspect of the invention, the maleimide, itaconimide and/or nadimide functional group of the maleimide, itaconimide and/or nadimide compound, respectively, is attached to a monovalent radical or the maleimide, itaconimide and/or nadimide functional groups of the maleimide, itaconimide and/or nadimide compound are separated by a polyvalent radical, each of the monovalent radical or the polyvalent radical having sufficient length and branching to render the maleimide and/or nadimide compound a liquid.

In a more specific recitation of such maleimide, itaconimide and nadimide of structures I, II and III, each R is independently hydrogen or lower alkyl, —X— comprises a branched chain alkyl, alkylene or alkylene oxide species having sufficient length and branching to render the maleimide, itaconimide or nadimide compound a liquid, and m is 1, 2 or 3.

The (meth)acrylates may be chosen from a host of different compounds. As used herein, the terms (meth)acrylic and (meth)acrylate are used synonymously with regard to the monomer and monomer-containing component. The terms (meth)acrylic and (meth)acrylate include acrylic, methacrylic, acrylate and methacrylate.

The (meth)acrylate component may comprise one or more members selected from a monomer represented by the formula: 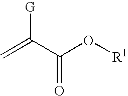
where G is hydrogen, halogen, or an alkyl having from 1 to 4 carbon atoms, R¹ has from 1 to 16 carbon atoms and is an alkyl, cycloalkyl, alkenyl, cycloalkenyl, alkaryl, aralkyl, or aryl group, optionally substituted or interrupted with silane, silicon, oxygen, halogen, carbonyl, hydroxyl, ester, carboxylic acid, urea, urethane, carbamate, amine, amide, sulfur, sulfonate, or sulfone;

urethane acrylates or ureide acrylates represented by the formula: 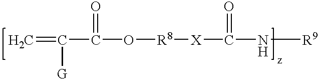
where

G is hydrogen, halogen, or an alkyl having from 1 to 4 carbon atoms;

R⁸ denotes a divalent aliphatic, cycloaliphatic, aromatic, or araliphatic group, bound through a carbon atom or carbon atoms thereof indicated at the —O— atom and —X— atom or group;

X is —O—, —NH—, or —N(alkyl)-, in which the alkyl radical has from 1 to 8 carbon atoms;

z is 2 to 6; and

R⁹ is a z-valent cycloaliphatic, aromatic, or araliphatic group bound through a carbon atom or carbon atoms thereof to the one or more NH groups; and

a di- or tri-(meth)acrylate selected from polyethylene glycol di(meth)acrylates, bisphenol-A di(meth)acrylates, tetrahydrofurane di(meth)acrylates, hexanediol di(meth)acrylate, trimethylol propane tri(meth)acrylate, or combinations thereof.

Suitable polymerizable (meth)acrylate monomers include triethylene glycol dimethacrylate, tripropylene glycol diacrylate, tetraethylene glycol dimethacrylate, diethylene glycol dimethacrylate, 1,4-butanediol diacrylate, 1,6-hexanediol dimethacrylate, pentaerythritol tetraacrylate, trimethylol propane triacrylate, trimethylol propane trimethacrylate, di-pentaerythritol monohydroxypentaacrylate, pentaerythritol triacrylate, bisphenol-A-ethoxylate dimethacrylate, trimethylolpropane ethoxylate triacrylate, trimethylolpropane propoxylate triacrylate, and bisphenol-A-diepoxide dimethacrylate.

Additionally, the (meth)acrylate monomers include polyethylene glycol di(meth)acrylates, bisphenol-A di(meth)acrylates, tetrahydrofurane(meth)acrylates and di(meth)acrylates, citronellyl acrylate and citronellyl methacrylate, hydroxypropyl(meth)acrylate, hexanediol di(meth)acrylate, trimethylol propane tri(meth)acrylate, tetrahydrodicyclopentadienyl(meth)acrylate, ethoxylated trimethylol propane triacrylate, triethylene glycol acrylate, triethylene glycol methacrylate, and combinations thereof.

Of course, (meth)acrylated silicones may also be used, provided the silicone backbone is not so large so as to minimize the effect of (meth)acrylate when cure occurs.

Other acrylates suitable for use herein include the low viscosity acrylates disclosed and claimed in U.S. Pat. No. 6,211,320 (Dershem), the disclosure of which is expressly incorporated herein by reference.

The fumarates include those comprising the following general structure: 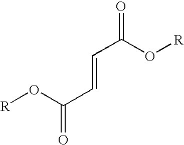
and the maleates include those comprising the following general structure: 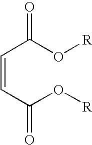
where R for each of the fumarates and maleates may be selected from R¹ as defined above.

The vinyl ethers and vinyl esters include those comprising the following general structure:
Y [symbol] Q_{0,1}-CR═CH₂R]_{q}
where

q is 1, 2 or 3,

each R is independently as defined above for R¹, each Q is independently selected from —O—, —O—C(O)—, —C(O)— or —C(O)—O—, and

Y is defined as X with respect to structures I, II and III above.

Examples of vinyl ethers or vinyl esters embraced by the above generic structure include stearyl vinyl ether, behenyl vinyl ether, eicosyl vinyl ether, isoeicosyl vinyl ether, isotetracosyl vinyl ether, poly(tetrahydrofuran)divinyl ether, tetraethylene glycol divinyl ether, tris-2,4,6-(1-vinyloxybutane-4-oxy-1,3,5-triazine, bis-1,3-(1-vinyloxybutane-4-)oxycarbonyl-benzene (alternately referred to as bis(4-vinyloxybutyl)isophthalate; available from Allied-Signal Inc., Morristown, N.J., under the trade name VECTOMER 4010), divinyl ethers prepared by transvinylation between lower vinyl ethers and higher molecular weight di-alcohols. Particularly desitrable divinyl resins include stearyl vinyl ether, behenyl vinyl ether, eicosyl vinyl ether, isoeicosyl vinyl ether, poly(tetrahydrofuran)divinyl ether, divinyl ethers prepared by transvinylation between lower vinyl ethers and higher molecular weight di-alcohols.

The styrene-containing component include those comprising the following general structure: 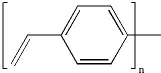
where n is 1-6, attached to X as defined above.

The norbornenyl component include those comprising the following general structure: 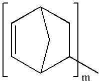
where m is is 1-6, attached to X as defined above.

The thiolene component include those comprising the following general structure: 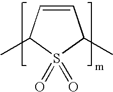
where m is is 1-6, attached to X as defined above.

As the allyl amides, a variety of compounds may be chosen, such as those satisfying the criteria set forth above with respect to the maleimides, itaconimides and/or nadimides. For instance, in a more specific representation, those corresponding to the following structure: 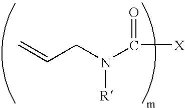
where

R′ is hydrogen, C₁ up to about C₁₈ alkyl or oxyalkyl, allyl, aryl, or substituted aryl,

m is 1-6, and

X is as defined above.

The free radically polymerizable component may be in the solid state at room temperature or in the liquid state at room temperature. When in the solid state, they may be used alone and blended into the composition at room temperature or under mildly elevated consitions. Alternatively, the free radically polymerizable component in the solid state may be dissolved in another component or additive of the inventive compositions, or in a liquid free radically polymerizable component.

As the cross linking agent, compounds having the following structure may be used:
A/C—X—FR,
where A/C represents at least one anionically or cationically reactive functional group, FR represents at least one free radically reactive functional group, and X represents a spacer, such as those set forth above. Examples of anionically reactive functional groups include epoxies, episulfides, nitrogen-containing compounds, such as amines, amides (such as dicyandiamide), imidazoles, azas, and cyanoacrylates. Examples of cationically reactive functional groups include epoxies, episulfides, anhydrides, organic acids, such as carboxylic acids, phenolics, thiophenolics, thiols and the like.

In that aspect of the invention directed to cross linking agent itself, where A/C is a carboxylic acid, then FR may not be maleimide and/or X may not be a five carbon straight chain alkyl group. Additionally, in the event that FR is maleimide and X is a five carbon straight chain alkyl group, then A/C may not be a carboxylic acid.

Examples of free radically reactive functional groups include maleimides, itaconimide, nadimides, (meth)acrylates, maleates, fumarates, vinyl ethers, vinyl esters, styrene and derivatives thereof, poly(alkenylene)s, allyl amides, norbornenyls, thiolenes and acrylonitriles.

For instance, epoxy or episulfide functionalized maleimide-containing compounds, epoxy or episulfide functionalized itaconimide-containing compounds, epoxy or episulfide functionalized nadimide-containing compounds, epoxy or episulfide functionalized (meth)acrylate-containing compounds, epoxy or episulfide functionalized maleate-containing compounds, epoxy or episulfide functionalized fumarate-containing compounds, epoxy or episulfide functionalized vinyl ether-containing compounds, epoxy or episulfide functionalized vinyl ester-containing compounds, epoxy or episulfide functionalized styrene-containing compounds, epoxy or episulfide functionalized poly(alkenylene)-containing compounds, epoxy or episulfide functionalized allyl amide-containing compounds, and like.

Particularly desirable cross linking agents include those prepared in accordance with Examples 1-3 below. In addition, commercially available maleinized polybutadiene resins sold by Sartomer, Inc., Exton, Pa. under the RICON trademark, such as RICON 130 products, with maleic anhydride percentages of 8, 13 or 20 are particularly desirable for use herein.

Certain maleimide-containing compounds useful in the practice of the present invention include, for example, maleimides having the following structures:

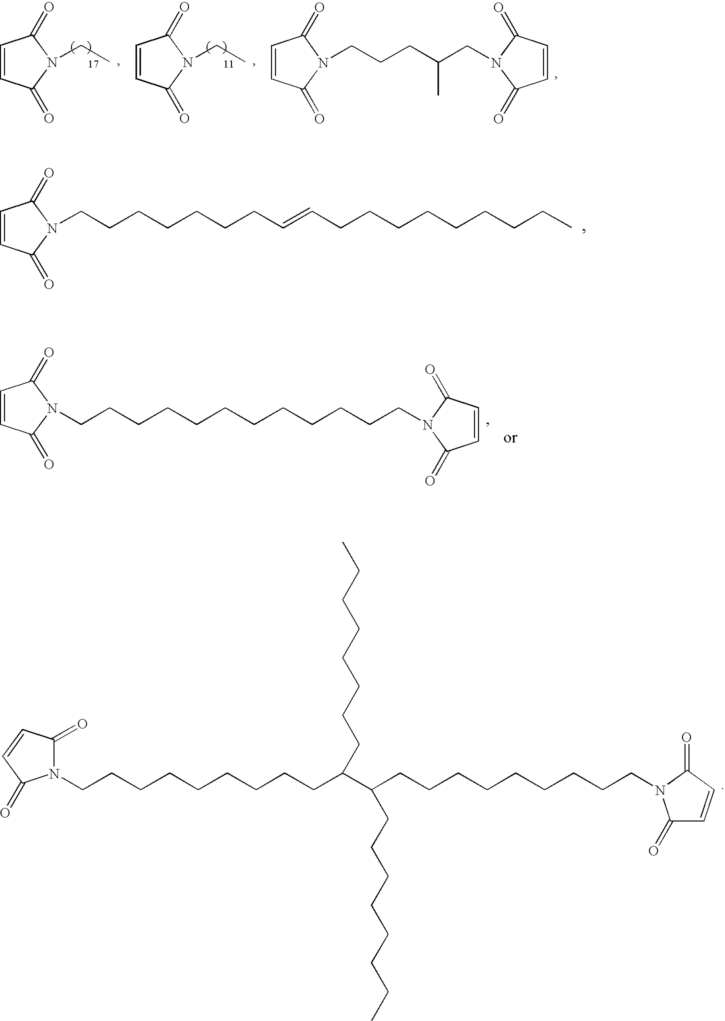

Additional maleimide-containing compounds of formula I include stearyl maleimide, oleyl maleimide and behenyl maleimide, 1,20-bismaleimido-10,11-dioctyl-eicosane, and the like, as well as combinations thereof.

Particularly desirable maleimide compounds embraced by formula I include bismaleimides prepared by reaction of maleic anhydride with dimer amides. An exemplary bismaleimide which can be prepared from such dimer amides is 1,20-bismaleimido-10,11-dioctyl-eicosane, which would likely exist in admixture with other isomeric species produced in the ene reactions employed to produce dimer acids. Other bismaleimides contemplated for use in the practice of the present invention include bismaleimides prepared from aminopropyl-terminated polydimethyl siloxanes (such as “PS510” sold by Hüls America, Piscataway, N.J.), polyoxypropylene amines (such as “D-230”, “D-400”, “D-2000” and “T-403”, sold by Texaco Chemical Company, Houston, Tex.), polytetramethyleneoxide-di-p-aminobenzoates (such as the family of such products sold by Air Products, Allentown, Pa., under the trade name “VERSALINK”, e.g., “VERSALINK” P-650), and the like. Preferred maleimide resins of formula I include stearyl maleimide, oleyl maleimide, behenyl maleimide, 1,20-bismaleimido-10,11-dioctyl-eicosane, and the like, as well as mixtures of any two or more thereof.

Bismaleimides can be prepared employing techniques well known to those of skill in the art, and as such will not be repeated here.

A radical cure inducing component may also be included, and when included desirably is a free radical initiator, triggered either by exposure to temperatures in the range of about 70° C. to about 200° C., or to radiation in the electromagnetic spectrum. As employed herein, the term “free radical initiator” refers to any chemical species which, upon exposure to sufficient energy (e.g., light, heat, or the like), decomposes into at least two species which are uncharged, but which each possesses at least one unpaired electron. Conditions suitable to cure the inventive composition include a temperature of less than 200° C. for about 0.25 up to 2 minutes.

The radical cure inducing component should be present in an amount of about 0.1 to about 5 weight percent, such as about 0.5 to about 2 weight percent.

Thermal free-radical cure initiators include for example, peroxides (e.g., peroxy esters, peroxy carbonates, hydroperoxides, alkylperoxides, arylperoxides, and the like), azo compounds, and the like. Presently preferred peroxides contemplated for use in the practice of the present invention include dicumyl peroxide, dibenzoyl peroxide, 2-butanone peroxide, tert-butyl perbenzoate, di-tert-butyl peroxide, 2,5-bis(tert-butylperoxy)-2,5-dimethylhexane, bis(tert-butyl peroxyisopropyl)benzene, tert-butyl hydroperoxide, and the like. Presently preferred azo compounds contemplated for use in the practice of the present invention include 2,2′-azobis(2-methylpropanenitrile), 2,2′-azobis(2-methylbutanenitrile), 1,1′-azobis(cyclohexanecarbonitrile), and the like.

Radiation free-radical cure initiators (or, photoinitiators) include for example, those commercially available from Vantico Inc., Brewster, New York under the tradename “IRGACURE” and “DAROCUR”, such as “IRGACURE” 184 (1-hydroxycyclohexyl phenyl ketone), 907 (2-methyl-1-[4-(methylthio)phenyl]-2-morpholino propan-1-one), 369 [2-benzyl-2-N,N-dimethylamino-1-(4-morpholinophenyl)-1-butanone], 500 (the combination of 1-hydroxy cyclohexyl phenyl ketone and benzophenone), 651 (2,2-dimethoxy-2-phenyl acetophenone), 1700 [the combination of bis(2,6-dimethoxybenzoyl-2,4,4-trimethyl pentyl) phosphine oxide and 2-hydroxy-2-methyl-1-phenyl-propan-1-one] and “DAROCUR” 1173 (2-hydroxy-2-methyl-1-phenyl-1-propane) and 4265 (the combination of 2,4,6-trimethylbenzoyldiphenyl-phosphine oxide and 2-hydroxy 2-methyl-1-phenyl-propan-1-one); photoinitiators available commercially from Union Carbide Chemicals and Plastics Co., Inc., Danbury, Conn. under the “CYRACURE” tradename, such as “CYRACURE” UVI-6974 (mixed triaryl sulfonium hexafluoroantimonate salts) and UVI-6990 (mixed triaryl sulfonium hexafluorophosphate salts); and the visible light [blue] photoinitiators, dl-camphorquinone and “IRGACURE” 784DC.

Additional photoinitiators may be chosen from those available from Sartomer, Inc., Exton, Pennsylvania under the tradenames “ESACURE” and “SARCAT”. Examples include “ESACURE” KBl (benzil dimethyl ketal), “ESACURE” EB3 (mixture of benzoin and butyl ethers), “ESACURE” TZT (trimethylbenzophenone blend), “ESACURE” KIP100F (hydroxy ketone), “ESACURE” KIP150 (polymeric hydroxy ketone), “ESACURE” KT37 (blend of “ESACURE” TZT and KIP150), “ESACURE” KT046 (blend of triphenyl phosphine oxide, “ESACURE” KIP150 and TZT), “ESACURE” X33 (blend of 2- and 4-isopropylthioxanthone, ethyl 4-(dimethyl amino)benzoate and “ESACURE” TZT], “SARCAT” CD 1010 [triaryl sulfonium hexafluoroantimonate (50% in propylene carbonate)], “SARCAT” DC 1011 [triaryl sulfonium hexafluorophosphate (50% n-propylene carbonate)], “SARCAT” DC 1012 (diaryl iodonium hexafluoroantimonate), and “SARCAT” K185 [triaryl sulfonium hexafluorophosphate (50% in propylene carbonate)].

Photoinitiators include triarylsulfonium and diaryliodonium salts containing non-nucleophilic counterions and aryl diazonium salts, examples of which include 4-methoxybenzenediazonium hexafluorophosphate, benzenediazonium tetrafluoroborate, diphenyl iodonium chloride, diphenyl iodonium hexafluorophosphate, 4,4-dioctyloxydiphenyl iodonium hexafluorophosphate, triphenylsulfonium tetrafluoroborate, diphenyltolylsulfonium hexafluorophosphate, phenylditolylsulfonium hexafluoroarsenate, and diphenyl-thiophenoxyphenylsulfonium hexafluoroantimonate.

Of course, combinations of such photoinitiators may be used as deemed appropriate by those of ordinary skill in the art.

The curative useful for the anionically or cationaically polymerzable component should be present in an amount of about 0.1 to about 20 weight percent, such as about 1 to about 10 weight percent.

As employed herein, the term “coupling agent” refers to chemical species which contain one set of functional groups capable of bonding to mineral and/or organic surfaces and which also contain another set of reactive functional groups capable of bonding to the reactive materials in the-die attach adhesive material. Coupling agents thus facilitate linkage of the die attach material to the substrate to which it is applied.

Exemplary coupling agents contemplated for use in the practice of the present invention include silicate esters, metal acrylate salts (e.g., aluminum methacrylate), titanates (e.g., titanium methacryloxyethylacetoacetate triisopropoxide), or compounds that contain a copolymerizable group and a chelating ligand (e.g., phosphine, mercaptan, acetoacetate, and the like). Generally in the range of about 0.1 up to 10 wt % of at least one coupling agent (based on the total weight of the organic phase) will be employed, within the range of about 0.5 up to 2 wt % preferred.

Certain desirable coupling agents contain both a co-polymerizable function (e.g., vinyl moiety, acrylate moiety, methacrylate moiety, styrene moiety, cyclopentadiene moiety, and the like), as well as a silicate ester function. The silicate ester portion of the coupling agent is capable of condensing with metal hydroxides present on the mineral surface of the substrate, while the co-polymerizable function is capable of co-polymerizing with the other reactive components of invention adhesive composition. An example of such a coupling agent is an oligomeric silicate coupling agent, such as poly(methoxyvinylsiloxane).

Other particularly desirable coupling agents include those represented by the structure:
Aₐ-L-Z_{b}
where each A is independently a free-radically polymerizable group; each L is independently a covalent bond or a polyvalent organic radical; each Z is independently a reactive moiety which forms hydrogen and/or covalent bond(s) with substrates having free hydroxyl groups on the surface thereof, a is 1-200, and b is 1-200.

Free-radically polymerizable groups, A, include optionally substituted maleimides, itaconimides, nadimides, optionally substituted vinyl ethers, optionally substituted vinyl thioether, optionally substituted vinyl esters, optionally substituted fumarates, optionally substituted vinyl thioester, optionally substituted diallyl amides, optionally substituted styrene functional groups, optionally substituted polybutadienyl, and the like. These functional groups can co-cure by a free-radical mechanism with, for instance, maleimides or (meth)acrylates when catalyzed by a small amount of free-radical inhibitor. Alternatively, such functional groups can also co-cure with such maleimides or acrylates without using free radical initiator, if the inventive composition is exposed to elevated cure temperatures, UV radiation, and the like, or combinations thereof.

Particularly desirable couple agents include maleimidopropyl trimethoxysilane, maleimidopropyl triethoxysilane, triethoxysilane derivative of ethylene glycol divinyl ether, triethoxysilane derivative of 5-vinyl-2-norbornene, and 3-methylmaleimidopropyl trimethoxysilane.

The co-curable composition may further include in the range of about 20 up to 90 wt % filler, based on the total weight of the composition. Fillers contemplated for use in the practice of the present invention may optionally be conductive (electrically and/or thermally). Electrically conductive fillers contemplated for use in the practice of the present invention include, for example, silver, nickel, gold, cobalt, copper, aluminum, graphite, silver-coated graphite, nickel-coated graphite, alloys of such metals, and the like, as well as mixtures thereof. Both powder and flake forms of filler may be used herein. In flake form, the filler may have a thickness of less than about 2 microns, with planar dimensions of about 20 to about 25 microns. Flake employed herein may have a surface area of about 0.15 to 5.0 m²/g and a tap density of about 0.4 up to about 5.5 g/cc. In powder form, the filler particles may have a diameter of about 0.5 to 30 microns, such as about 20 microns.

Thermally conductive fillers contemplated for use in the practice of the present invention include, for example, aluminum nitride, boron nitride, silicon carbide, diamond, graphite, beryllium oxide, magnesia, silica, alumina, and the like.

Electrically and/or thermally conductive fillers should be rendered substantially free of catalytically active metal ions by treatment with chelating agents, reducing agents, nonionic lubricating agents, or mixtures of such agents. Such treatment is described in U.S. Pat. No. 5,447,988, which is expressly incorporated by reference herein in its entirety.

Optionally, a filler may be used that is neither electrically nor thermally conductive. Such fillers may be desirable to impart some other property to the formulation such as, for example, reduced thermal expansion of the cured composition, reduced dielectric constant, improved toughness, increased hydrophobicity, and the like. Examples of such fillers include perfluorinated hydrocarbon polymers (i.e., TEFLON), thermoplastic polymers, thermoplastic elastomers, mica, fused silica, glass powder, spacer elements and the like.

The composition may be substantially free of non-reactive diluent, or depending on the constituents used.

When a diluent is added, it is desirable for the diluent to be a reactive diluent which, in combination with the maleimide-containing compound, forms a thermosetting resin composition. Such reactive diluents include acrylates and methacrylates of monofunctional and polyfunctional alcohols, vinyl compounds as described in greater detail herein, styrenic monomers (i.e., ethers derived from the reaction of vinyl benzyl chlorides with mono-, di-, or trifunctional hydroxy compounds), and the like.

The inventive composition may further contain other additives, such as defoaming agents, leveling agents, dyes, and pigments.

The inventive composition may be applied by stencil printing, screen printing or spray coating. In the case of stencil printing or screen printing onto pre-diced wafers, the wafers can be uniformly coated with the inventive composition. During wafer dicing, the dicing saw then cuts completely through the layer of the inventive composition and the wafer.

In the case of stencil printing or screen printing onto diced wafers, the stencil or screen is made with apertures designed to partially, not completely, coat the individual die or semiconductor chips. Specifically, the webbing of the stencil or screen is used to maintain the inventive composition in place. That is, it is undesirable for the die attach adhesive material to enter into the dicing streets, which would facilitate die separation during die placement. The width of the webbing, or conversely, the dimensions of the aperture, are designed so that after die placement, the target wet bondline may be achieved and the inventive composition may form fillets of the desired height beneath the die.

In the case of stencil printing or screen printing onto laminate substrates, the stencil or screen is made with apertures designed to partially coat the die pad. Specifically, the webbing of the screen or stencil is used to maintain in place the inventive composition after die placement. The width of the webbing, or conversely, the dimensions of the aperture, are designed so that after die placement, the target wet bondline may be achieved and the inventive composition may form fillets of the desired height beneath the die with minimal to no wetting by the inventive composition of the electrically conductive interconnects.

In the case of application onto laminate substrates, a “zero gap bondline” may be achieved with the inventive composition. For instance, the laminate is first manufactured without a solder mask layer over the die pad. Thus, the die pad area is lower in height relative to the non-die pad areas by a depth equal to the thickness of the solder mask layer, which is typically around 1 mil. These recessed die pads are then filled with the inventive composition, using stencil printing or screen printing.

Preferably, an amount of inventive composition is applied until the surface of the applied adhesive material is flush with the solder mask layer. The recessed die pad is not completely filled in with the inventive composition; rather, an amount of the inventive composition is used such that after die placement, the inventive composition has flowed underneath the die to cover the previously exposed die pad bottom. This method allows for semiconductor packaging manufacturers to achieve thinner packages without changing the bondline adhesive.

In the case of spray coating, thin semiconductor wafers are desirable substrates on which to coat the inventive composition. These thin semiconductor wafers have thickness of about 2-3 mil. Although mechanically robust once properly supported, i.e., bonded onto flexible subtrates and encapsulated or overmolded, in their unsupported form thin dice derived from these wafers are fragile and break rather easily. It is therefore advantageous that a method for applying inventive composition onto thin wafers apply minimal force while doing so.

After the inventive composition has been applied onto the wafer or die using any of the above methods, the adhesive material may then be dried to remove solvent, if present, or cooled to solidify the adhesive material.

A typical drying time may be about 30 minutes at a temperature of about 100° C., though any temperature below the cure onset of the curable componenets of the inventive composition may be chosen. The length of time may vary depending on the time required for the surface of the inventive composition to become tack free at the chosen temperature.

Any time after the surface of the inventive composition is tack free (either by drying or cooling), die bonding may occur.

Conditions suitable for curing the inventive composition include subjecting invention film adhesive compositions to a temperature of at least about 175° C. but less than about 300° C. for about 0.5 up to about 2 minutes. A typical die bonding setting is a time of about 10 seconds at a temperature of about 100° C. using 500 cN spread, in the case of a 7.6 mm×7.6 mm die. This rapid, short duration heating can be accomplished in a variety of ways, e.g., with in-line snap cure stations such as those manufactured by Nihon Sanso, a heated stage mounted on the diebonder, or an IR beam provided by an EFOS Novacure IR unit.

The die can be heated by pulsing heat through the die collet, which is an available feature in film diebonders, such as those manufactured by ESC. In the case of thin die which are typically warped due to the build-up of residual mechanical stress during the grinding process, heating the die above a certain temperature has the effect of annealing the die and reducing warpage.

### EXAMPLES

In Examples 1-3, cross linking agents in accordance with the invention have been prepared, as so described.

### Example 1

Triethylamine (24.6 g, 0.2 mol) and methanesulfonic acid (26.0 g, 0.26 mol) were placed into a three-neck round-bottom flask, fitted with a Dean-Stark trap, and dissolved in toluene (200 ml). This mixture was stirred at room temperature for a period of time of 30 minutes, at which time maleic anhydride (20.5 g, 0.21 mol) was added, followed by 11-aminoundecanoic acid (40.2 g, 0.2 mobl) during a half hour period of time. The reaction mixture was heated to reflux while stirring for a period of 24 hours, with the water generated from the reaction collected by the Dean-Stark trap.

After cooling to room temperature, the reaction mixture was separate by a separation funnel, and passed through a filtration funnel with a thin layer of silica gel. The toluene was removed under vacuum to give as a white solid, 11-maleimido-undecanoic acid, in a 78% yield.

### Example 2

Triethylamine (24.6 g, 0.2 mol), methanesulfonic acid (26.0 g, 0.26 mol), toluene (200 ml), maleic anhydride (20.5 g, 0.21 mol), and 4-aminobenzoic acid (27.4 g, 0.2 mol), were used in this example, and the procedure was followed as described in Example 1. The product, 4-maleimido-benzoic acid, a yellow solid, was obtained in a 64% yield.

### Example 3

A cross linking agent in accordance with this invention was prepared in accordance with the following synthetic equation: 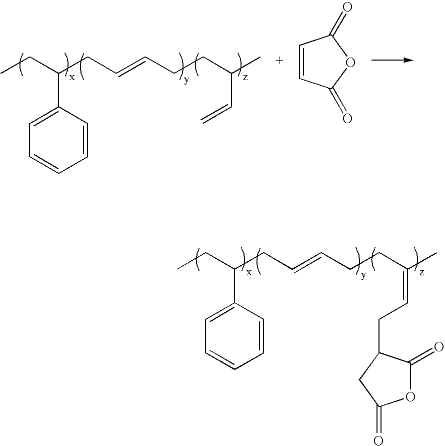
where the mole ratio of x+y+z=1, and the greater mole fraction of y and z results in a cross linking agent with greater functionality available to react with the anionically or cationically polymerizable component and the free radical polymerizable component, thereby resulting in higher degree of cross linking. Of course, those persons of ordinary skill n the art will make appropriate choices for the values of x, y and z by modifying reactant stoichiometries and reaction conditions so as to prepare a cross linking agent with the proper amount of functionality for the desired end use.

KRATON (from Shell Chemical, 30 g) and maleic anhydride (3.2 g) were dissolved in 250 ml of toluene, placed into a pressure Porr reactor, and heated with stirring to a temperature within the range of 180-220° C. for a period of time of 24 hours. After this time, the reaction mixture was cooled to room temperature, passed thorough a thin layer of silica gel, and the solvent removed to give an amorphous solid.

### Example 4

In this example, co-curable compositions in accordance with this invention (Sample Nos. 1 and 2) were prepared from the noted constituents in the respective amounts in grams as set forth below in Table 1:

TABLE 1

| Type | Identity | 1 | 2 |
|---|---|---|---|
| Epoxy | EPON 8132 | 0.46 | 0.46 |
| Maleimide | X-BMI¹ | 1.39 | 1.39 |
| (Meth)acrylate | Isobornyl methacrylate | 0.76 | 0.76 |
| | 2-Phenoxyethyl acrylate | 0.58 | 0.58 |
| | LVM (meth) acrylate² | 0.25 | 0.25 |
| Cross Linking | RICON 130³ | 0.24 | — |
| Agent | | | |
| Coupling Agent | 3-methylmaleimido | 0.17 | 0.17 |
| | propyltrimethoxysilane | | |
| Filler | Silver flake | 16 | 16 |
| Curative -- | Dicyandiamide | 0.05 | 0.05 |
| epoxy | | | |
| Free radical | 1,1-di(tert-amylperoxy | 0.1 | 0.1 |
| catalayst | cyclohexane⁴ | | |

¹X-BMI (the 1,20-bismaleimido derivative of 10,11-dioctyl-eicosane), was prepared accordinq to the procedure set forth in U.S. Pat. No. 5,973,166, the disclosure of which is hereby expressly incorporated herein by reference.
²LVM (meth) acrylate was prepared according to Example 1 of U.S. Pat. No. 6,211,320 (Dershem), the disclosure of which is hereby expressly incorporated herein by reference.
³Polybutadiene grafted with 20 weight percent maleic anhydride, available commercially from Sartomer, Inc., Exton, PA.
⁴USP90MD, available commercially from Witco.

Sample Nos. 1 and 2 were prepared by mixing together the recited components for about 10 to 15 minutes at room temperature. An aliqout of each of the samples was placed on a substrate, a silicon die was then placed onto the aliquot, and the assembly was cured to a temperature of 185° C. for 30 minutes.

The samples were evaluated for room temperature die shear and hot die shear at 245° C. on a calibrated Dage 2400 die shear tester at a rate of 19 mil/sec. The results measured in Kgf for 300² die on Ag—Cu substrates are shown below in Table 2.

TABLE 2

| Physical | | |
|---|---|---|
| Property | 1 | 2 |
| RT | 99.7 ± 0.9 | 17.4 ± 6.8 |
| 245° C. | 13.8 ± 2.6 | 3.2 ± 1.0 |

1. A curable composition, comprising:
(a) an epoxy or episulfide resin component;
(b) a free radical polymerizable component; and
(c) a cross linking component, wherein the cross linking component comprises a compound
(i) reactive with each of the epoxy resin component and the free radical polymerizable component, or
(ii) functionalized with
a. at least one group reactive with the epoxy or episulfide resin component and at least one group reactive with the free radical polymerizable component, or
b. at least one group reactive through an anionic or cationic mechanism with the epoxy or episulfide resin component and at least one group reactive through a free radical mechanism with the free radical polymerizable component.

2. The composition of claim 1, further comprising a free radical initiator for the free radical polymerizable component, a curative for the epoxy or episulfide resin component, and combinations thereof.

3. (canceled)

4. The composition of claim 3, wherein the curative comprises a member selected from the group consisting of nitrogen containing compounds, anhydrides, organic acids and Lewis acids.

5. (canceled)

6. The composition of claim 1, wherein the free radical polymerizable component comprises a maleimide-containing compound, an itaconimide-containing compound, or nadimide-containing compound.

7. The composition of claim 6, wherein the maleimide-containing compound, itaconimide-contaning compound or nadimide-containing compound comprises 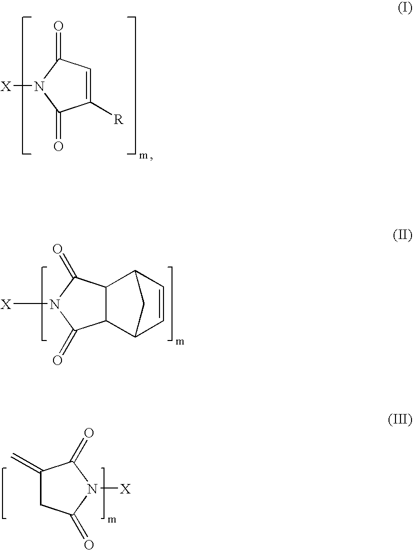
wherein:
m=—1-15;
R is independently selected from hydrogen or lower alkyl, and
X is a monovalent moiety or a multivalent linking moiety comprising organic or organosiloxane radicals, and combinations thereof.

8. The composition of claim 1, wherein the maleimide-containing compound or nadimide-containing compound is in the solid state at room temperature.

9. The composition of claim 6, wherein the maleimide-containing compound, itaconimide-containing compound or nadimide-containing compound comprises: 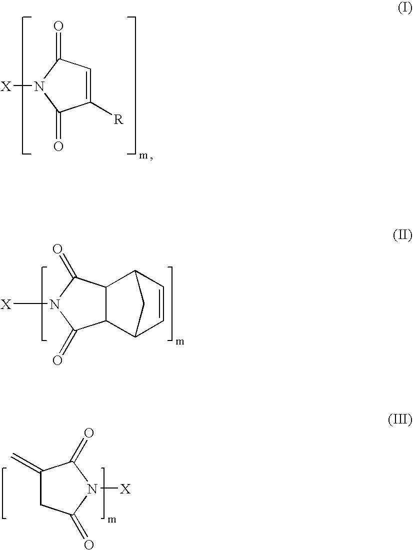
wherein:
m=1-6,
R is independently selected from hydrogen or lower alkyl, and
X comprises a monovalent moiety or a multivalent linking moiety selected from
(A) straight or branched chain alkyl, alkylene, oxyalkyl, oxyalkylene, alkenyl, alkenylene, oxyalkenyl, oxyalkenylene, ester, reverse ester, polyester, amide, reverse amide, or polyamide, optionally interrupted or substituted by one or more heteroatoms, such as oxygen, nitrogen and/or sulfur, and optionally functionalized with substituents selected from hydroxy, alkoxy, carboxy, nitrile, cycloalkyl or cycloalkenyl; where the number of carbon atoms in the linking moeity falls between about 12 to about 500;
(B) siloxanes comprising:
—(CR₂)_{m′}—[Si(R′)₂—O]_{q′}—Si(R′)₂—(CR₂)_{n′}—, —(CR₂)_{m′}—CR—C(O)O—(CR₂)_{m′}—[Si(R′)₂—O]_{q′}—Si(R′)₂—(CR₂)_{n′}—O(O)C—(CR₂)_{n′}— or —(CR₂)_{m′}—CR—O(O)C—(CR₂)_{m′}—[Si(R′)₂—O]_{q′}—Si(R)₂—(CR₂)_{n′}—C(O)O—(CR₂)_{n′}— wherein each R is independently defined as above, and each R′ is independently selected from hydrogen, lower alkyl or aryl, m′ falls in the range of 1 up to 10, n′ falls in the range of 1 up to 10, and q′ falls in the range of 1 up to 50;
(C) polyalkylene oxides comprising:
—[(CR₂)ᵣ—O—]_{q′}—(CR₂)ₛ—
wherein each R is independently as defined above, r falls in the range of 1 up to 10, s falls in the range of 1 up to 10, and q′ is as defined above;
(D) aromatic moieties comprising: 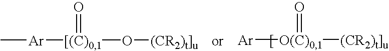
wherein each R is independently as defined above, t falls in the range of 2 up to 10, u is 1, 2 or 3, and Ar is as defined above, or 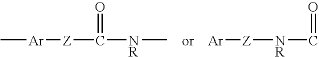
wherein Z is O or NR, where R is hydrogen or lower alkyl;
(E) urethanes comprising: 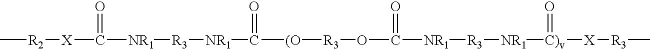
wherein each R₁ is independently hydrogen or lower alkyl; each R₂ independently is an alkyl, aryl, or arylalkyl group having 1 to 18 carbon atoms; R₃ is an alkyl or alkyloxy chain having up to about 100 atoms in the chain, which chain may contain aryl substituents; X is O, S, N, or P; and v is 0 to 50; and
(F) aromatic moieties comprising: 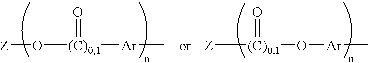
wherein each Ar is a monosubstituted, disubstituted or trisubstituted aromatic or heteroaromatic ring having in the range of 3 up to about 10 carbon atoms; n is 1 up to about 50, and Z is selected from straight or branched chain alkyl, alkylene, oxyalkylene, alkenyl, alkenylene, oxyalkenylene, ester, or polyester, optionally containing substituents selected from hydroxy, alkoxy, carboxy, nitrile, cycloalkyl or cycloalkenyl; and
(G) polyalkylene oxides comprising:
—[(CR₂)ᵣ—O—]_{q′}—(CR₂)ₛ—
wherein each R is independently as defined above, r falls in the range of 1 up to 10, s falls in the range of 1 up to 10, and q′ is as defined above; as well as combinations thereof.

10. The composition of claim 6, wherein the maleimide-containing compound, the itaconimide-containing compound, or the nadimide-containing compound comprises a maleimide functional group, itaconimide-containing functional group or a nadimide functional group, respectively, attached to a monovalent radical or polyvalent radical having sufficient length and branching to render the maleimide-containing compound, the itaconimide-containing compound or the nadimide-containing compound, respectively, a liquid.

11. The composition of claim 6, wherein the maleimide-containing compound, the itaconimide-containing compound or the nadimide-containing compound comprises: 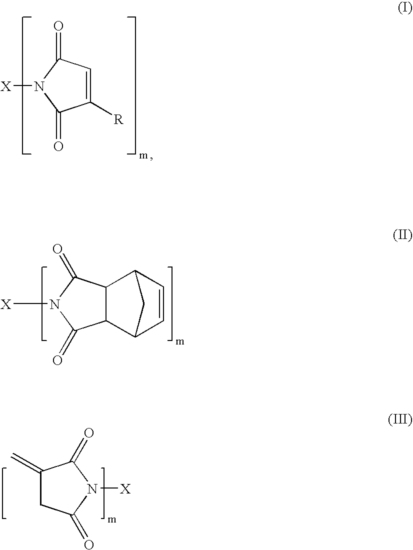
wherein:
each R is independently hydrogen or lower alkyl, —X— comprises a branched chain alkyl, alkylene or alkylene oxide species having sufficient length and branching to render the maleimide-containing compound, the itaconimide-containing compound or the nadimide-containing compound a liquid, and
m is 1, 2 or 3.

12. The composition of claim 1, wherein the free radical polymerizable component comprises a member selected from the group consisting of (meth)acrylates, maleimides, itaconimides, nadimides, vinyl ethers, vinyl esters, styrene and derivatives thereof, poly(alkenylene)s, allyl amides, norbornenyls, thiolenes, acrylonitriles and combinations thereof.

13-15. (canceled)

16. A curable composition, comprising:
(a) an anionically or cationically reactive component;
(b) a free radical polymerizable component; and
(c) a cross linking component, wherein the cross linking component comprises a compound having at least one functional group reactive with the anionically or cationically reactive component and at least one functional group reactive with the free radical polymerizable component.

17. The composition of claim 1, wherein the at least one functional group reactive through an anionic or cationic mechanism with the epoxy or episulfide resin component is a member selected from the group consisting of epoxies, episulfides, and combinations thereof.

18. The composition of claim 1, wherein the at least one functional group reactive through a free radical mechanism with the free radical polymerizable component is a member selected from the group consisting of (meth)acrylates, maleimides, itaconimides, nadimides, vinyl ethers, vinyl esters, styrenes, allyl amides, norbornenes and combinations thereof.

19. The composition of claim 1, wherein the cross linking component comprises a compound having the structure:
A/C—X—FR,
wherein A/C represents at least one anionically or cationically reactive functional group, FR represents at least one free radically reactive functional group, and X represents a spacer.

20. The composition of claim 1, wherein A/C is E/ES, wherein E/ES represents at least one epoxy or episulfide.

21. (canceled)

22. A cross-linking compound comprising
A/C—X—FR,
wherein A/C represents at least one anionically or cationically reactive functional group or at least one epoxy or episulfide, FR represents at least one free radically reactive functional group, and X represents a spacer, provided that when A/C is not carboxylic acid, FR may be maleimide and/or X may be a five carbon straight chain alkyl group, when FR is not maleimide and X is not a five carbon straight chain alkyl group, A/C may be a carboxylic acid, when A/C is not maleic anhydride, FR is a polybutadiene or when FR is not a polybutadiene, A/C is maleic anhydride, 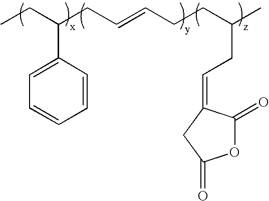
wherein the mole ratio of x+y+z=1, and combinations thereof.

23-27. (canceled)

28. A method for adhesively attaching a chip die to another chip die or a circuit board, said method comprising:
(a) applying the composition of claim 1 to said chip die,
(b) adjoining said chip die with said another chip die or said circuit board, respectively, to form an assembly wherein said chip die and said another chip die or said circuit board, respectively, are separated by the composition applied in step (a), and
(c) subjecting said assembly formed in step (b) to conditions suitable to cure said composition.

29-33. (canceled)

34. The composition of claim 1, further comprising a filler.

35-38. (canceled)

39. An article of manufacture comprising a semiconductor chip attached to and in electrical interconnection with either another semiconductor chip or a carrier substrate, the semiconductor chip having a first surface and a second surface, with the first surface having electrical contacts arranged in a predetermined pattern thereon for providing electrical engagement with the another semiconductor chip or the carrier substrate, respectively, and with the second surface having a cured composition of claim 1 disposed on a layer or a portion thereof, so as to provide attachment between the semiconductor chip and the another semiconductor chip or the carrier substrate, respectively.
